(19) United States
(12) Patent Application Publication
(10) Pub. No.: US 2011/0073289 A1
(43) Pub. Date: Mar. 31, 2011

(54) LOW PROFILE BLOWER RADIAL HEATSINK

(76) Inventor: KETAN R. SHAH, Olympia, WA (US)

(21) Appl. No.: 12/567,552

(22) Filed: Sep. 25, 2009

(51) Int. Cl. H01L 23/467; F04D 29/44; F04D 25/16; F28F 13/12

(52) U.S. Cl. 165/122; 415/203; 415/60; 165/80.3

(57) ABSTRACT

A cooling device, such as for cooling a chip and socket may have a centrifugal blower outside of a radial heatsink. In addition, supports for coupling the blower to a center motor may comprise overhead fan blades effectively creating a radial fan in series with the blower to maximize airflow and pressure capability and to minimize the noise. The vertical location of blower may further allow to improve motherboard component as well as system cooling all while reducing the vertical profile of the cooling device.

### FIELD OF THE INVENTION

Embodiments of the present invention are directed to cooling electronic devices and, more particularly, to a centrifugal blower and radial heatsink device suitable for low profile devices, such as, for example, low profile desktop, laptop, and notebook computers.

### BACKGROUND INFORMATION

Integrated circuit devices (hereinafter “ICs”) and other types of electronic components, are becoming increasingly powerful as new features and capabilities are continuously being introduced. This is particularly true regarding the packaging of ICs on substrates, where each new generation of packaging must provide increased performance, particularly in terms of an increased number of components and higher clock frequencies, while generally being smaller or more compact in size. Because these powerful, yet tiny devices are experiencing a relatively large amount of electrical current flow within an extremely small area, a substantial amount of heat is generated during use. If this heat is not continuously removed, these devices may overheat, resulting in damage to the device, the entire system, and/or a reduction in operating performance. As a result, cooling devices are often used in conjunction with electronic components, assemblies and systems.

One commonly used cooling device is a heat dissipation device or heat sink cooling device. This device is normally secured to the top of the electronic component or assembly. In many instances, a fan is used in conjunction with the heat sink to aid in cooling. The heat sink portion of this device typically includes any number of vertically-oriented or prismatic cooling fins or rods that increase the surface area of the heat sink, thus maximizing the transfer of heat from the heat sink device into the surrounding air.

The fan, which is typically mounted on top of the heat sink, causes air to move in a manner that helps to cool the fins or rods, thus enhancing their cooling effect. In smaller devices, such as notebook computers and the like, a fan operating at traditional speeds may not provide enough airflow thus necessitating the fan to be run at higher speeds, adding blades, or perhaps increasing blade pitch all of which may only marginally increase airflow as compared to the relatively large increase in unwanted noise and power consumption. Designers are ever aware of these issues since power consumption has long been an issue and not do consumers want longer battery life and less noise but governments and other regulatory groups are beginning to impose stringent acoustic noise levels for such devices.

For the reasons stated above, and for other reasons stated below which will become apparent to those skilled in the art upon reading and understanding the present specification, there is a need in the art for a more efficient heat sink and airflow solution.

### BRIEF DESCRIPTION OF THE DRAWINGS

The foregoing and a better understanding of the present invention may become apparent from the following detailed description of arrangements and example embodiments and the claims when read in connection with the accompanying drawings, all forming a part of the disclosure of this invention. While the foregoing and following written and illustrated disclosure focuses on disclosing arrangements and example embodiments of the invention, it should be clearly understood that the same is by way of illustration and example only and the invention is not limited thereto.

FIG. 1 is a plan view of the low profile radial blower according to one embodiment of the invention;

FIG. 2 is a cut-away view of the low profile blower shown in FIG. 1;

FIG. 3 is a top cut-away view of the low profile blower; and

FIG. 4 is a close-up top cut-away view of the low profile blower showing the relation of the rotation of the centrifugal blower and the radial heatsink fins.

### DETAILED DESCRIPTION

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

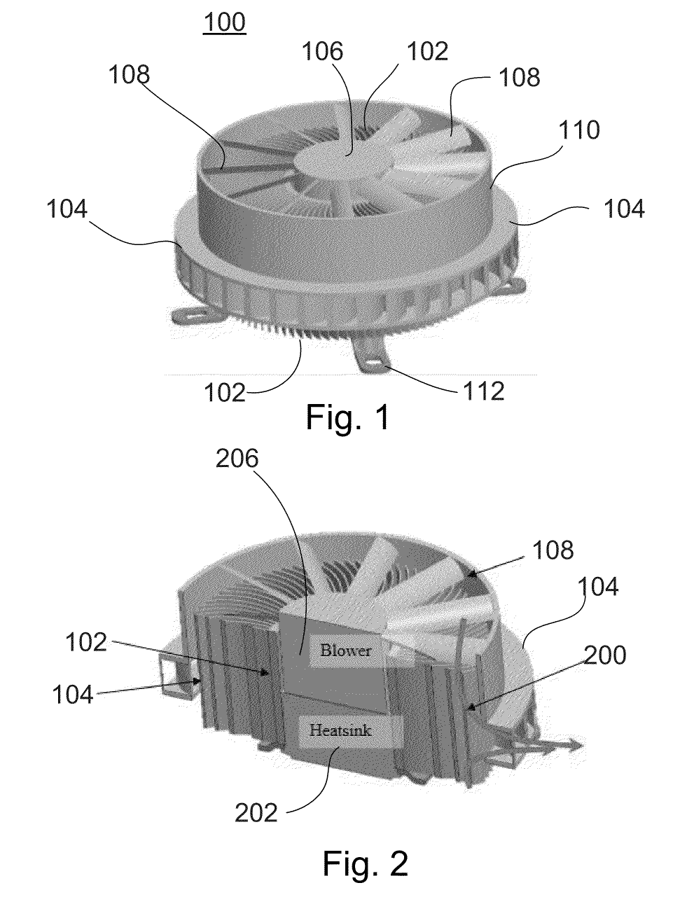

Referring now to FIG. 1, there is shown a Cooling device 100 comprising radial fin heatsink 102 with an outer centrifugal blower 104 located outside and surrounding the radial fin heatsink 102. A center hub 106 may have axial blades 108 connected to an outer cylindrical cowling 110 having the centrifugal blower 104 that may be located near the bottom portion of the cowling 110. Legs 112 may also be provide for attaching the device 100 to a board.

FIG. 2 shows a cut-away view of the device 100 shown in FIG. 1. The radial fin heatsink 102 with centrifugal blower 104 outside utilizes the centrifugal airflow vectors, illustrated by arrows 200, from inside to outside to cool a chip attached to the center of the heatsink core 202. The blower 104 being outside has a larger diameter which allows the blower 104 to spin slower and quieter while providing the needed airflow for cooling. In one embodiment, the radial fins 102 of the heatsink may be curved, as shown, to not only maximize the fin surface area but also to align the upstream flow vectors such as to minimize swirl (or circumferential turning) and associated pressure loss.

The outside blower 104 also does not need vertical height above the heatsink 202 and so allows for thinner profiles. An electric motor 206 to drive the blower 104 may be located in the volume above the heatsink core 202 to maintain compactness.

The blower blades 104 may be connected to the motor 206 through a plastic support that will rotate with the blades of the blower 104. The plastic support piece or axial blades 108 may have the open area to allow the airflow to pass through it from the top side. The axial blades 104 may be used to provide the combination of an axial airflow fan and a centrifugal blower 104 to maximize the airflow and cooling or to minimize the acoustics. In operation, the center hub 106 that joins the blower 104 to the motor 206 on top of the heatsink 202 is also rotating and so can utilize the airfoil fan blades to further increase the airflow and/or capability to work against the high fin density heatsink 104 providing significantly better chip cooling.

The overall response is similar to having a fan, comprising the axial blades 108, and centrifugal blower 104 in series and can combine to provide the better flow capability of the fan and better pressure capability of the blower. The rotations per minute (RPM) of fan 108 and blower 104 would be the same but the number of blades comprising the fan 108 and blower 104 may be modified to provide the optimal operating point of flow and pressure. The combination of axial fan 108 and blower 104 may overall provide iso-acoustics, much better airflow and chip cooling capability.

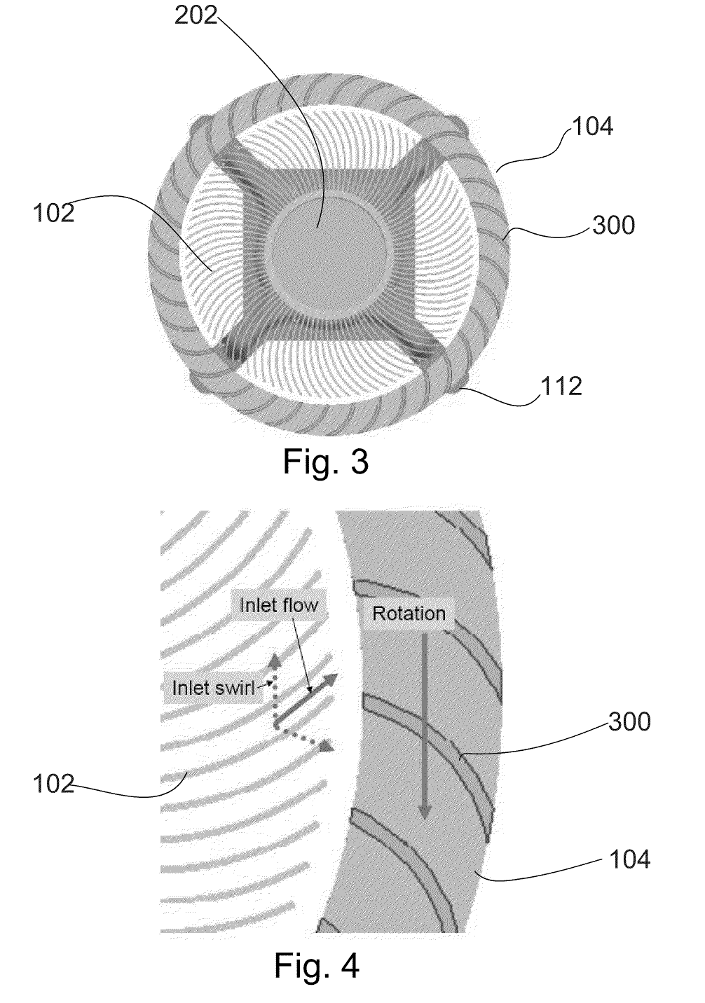

FIG. 3 shows a cut-away top view of the centrifugal blower 104 and radial fin heatsink 202. The heatsink 202 may be located on a device, such as a chip, to be cooled. A plurality of fins 102 project radially from the core portion of the heatsink 202. As noted above, these fins 102 may be curved to increase surface area and to align upstream flow vectors to minimize swirl and associated pressure losses. The centrifugal blower 104 may be located coaxial with the heatsink 202 at the periphery of the fins 102 and may also comprise a plurality of blower blades 300. These blower blades 300 may also be curved in an opposite direction to the curve of the fins 102.

As shown in FIG. 4, the radial heatsink fins 102 remain stationary in operation as the centrifugal blower rotates in a direction as indicated by the arrow. This causes cooler air to be drawn in from above and beneath the device as indicated by the air inlet flow vectors creating an inlet swirl, thus cooling the fins 102 as the warm air is exhausted through the centrifugal blower 104. This airflow may of course be aided by the addition of the rotation of the axial blades spinning at the same rate as the blower 104 as shown in FIG. 1.

The inside to outside centrifugal airflow can be provided from either top of the heatsink or also from the bottom as shown by the arrows. The bottom side airflow can be used to augment the voltage regulator and socket cooling. The inlet from the bottom may be controlled with a duct or structural clip underneath as well as with the vertical location of blower blades 300.

An initial calculation has shown that, for example, a 65W desktop processors may be cooled by the invention with 1.5 inch total height from the motherboard (MB) instead of the present 2.1 inch profile and thus using embodiments of the invention, the z-height profile may be lowered by about 0.6 inch or 15 mm and still provide adequate cooling at acceptable acoustic levels.

Embodiments of the present invention provide many advantages, not the least of which is a lower z-height profile. Present desktop processor cooling solutions use an axial fan on top of a radial heatsink. The depth of a fan varies from 15-30 mm and so does not easily allow heatsinks thinner than 40 mm (and system thicknesses below 75 mm). The up-coming uSFF (ultra small form factor) and AIO (all-in-one) systems use thinner heatsinks and hence presently they use either a heatpipe heatsink and/or lower power processors. The blower outside solution according to the present invention with thin struts (instead of fan blades) on the top side can effectively remove the 15-30 mm vertical height in the stack allowing for thinner systems. The same thermal performance may require larger horizontal area which is more easily available with large display screen AIO and with 2-chip platform transition.

The operation is also quieter than previous solutions due in part to the larger diameter blower. The outside blower can naturally have larger diameter and hence can provide for the same airflow at lower acoustics. The effective fan in series can allow further reduction in RPM at iso-flow condition lowering the noise further. The natural airflow vectors for the blower are radial outside due to centrifugal force. In contrast, conventional blowers utilize the

The radial heatsink with blower outside concept utilizes that to maximize the airflow/pressure capability. The outside blower concept also generates large radially emanating airflow in a system that can assist in cooling the motherboard components such as the socket, voltage regulation, and chipsets and memory. The curvature in heatsink fins and the blade geometry can be used to induce the inlet swirl opposite to the direction of rotation and reduce the downstream or outlet swirl and provide the radial outlet for downstream cooling.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize.

These modifications can be made to the invention in light of the above detailed description. The terms used in the following claims should not be construed to limit the invention to the specific embodiments disclosed in the specification and the claims. Rather, the scope of the invention is to be determined entirely by the following claims, which are to be construed in accordance with established doctrines of claim interpretation.

What is claimed is:

1. An apparatus, comprising:
a cylindrical cowling;
a centrifugal blower positioned near a bottom portion of the cylindrical cowling;
a plurality of vertical blades comprising the centrifugal blower
a central hub coaxially located at a top portion of the cowling;
a plurality of supports radiating from the central hub and connected to top portion of the cylindrical cowling; and
a motor for spinning the central hub along with the cylindrical cowling and the centrifugal blower.

2. The apparatus as recited in claim 1 wherein the plurality of supports are shaped as blades forming an axial fan over the top portion of the cylindrical cowling.

3. The apparatus as recited in claim 2 wherein the axial fan and the centrifugal blower comprise two air movement devices in series.

4. The apparatus as recited in claim 1, further comprising:
a radial fin heat sink positioned coaxial within the cowling.

5. The apparatus as recited in claim 4 wherein the radial fin heat sink comprises a central heatsink core positioned adjacent the motor with a plurality of fins radiating there from.

6. The apparatus as recited in claim 5 wherein the plurality of fins are curved to increase surface area.

7. The apparatus as recited in claim 6 wherein the centrifugal blower comprises a plurality of vertical blades curved in an opposite direction in relation to the curve of the plurality of curved fins.

8. A method for cooling a device, comprising:
placing a heatsink in thermal contact with a device to be cooled;
surrounding the heatsink with a cylindrical cowling;
providing a centrifugal blower near a bottom portion of the cylindrical cowling;
connecting an axial fan to a top portion of the cylindrical cowling;
spinning the axial fan which also causes the cylindrical cowling to spin and the centrifugal blower to spin.

9. The method as recited in claim further comprising:
providing a plurality of fins radiating from a central portion of the heatsink toward an interior surface of the cylindrical cowling but not touching the interior surface.

10. The method as recited in claim 9 further comprising:
curving each of the plurality of fins to increase surface area of the fins.

11. The method as recited in claim 10 further comprising:
providing a plurality of vertical blades within the centrifugal blower.

12. The method as recited in claim 11 further comprising each of the plurality of vertical blades in a direction opposite the curve of the plurality of fins.

13. The method as recited in claim wherein the axial fan and the centrifugal blower comprise two air movement devices in series and spun by the same motor.

14. A system for cooling an electronic device with two air movement devices in series, comprising:
a heatsink to draw heat from an electronic device, the heatsink comprising a core portion and a plurality of radial fins;
a cylindrical cowling located around the heatsink;
an axial fan connected to a top portion of the cylindrical cowling;
a centrifugal blower positioned coaxial with the cylindrical cowling.

15. The system as recited in claim 14 further comprising a motor to spin the axial fan also causing the cylindrical cowling and the centrifugal blower to spin.

16. The system as recited in claim 14 wherein the plurality of radial fins are curved to increase surface area.

17. The system as recited in claim 16 further comprising:
providing a plurality of vertical blades within the centrifugal blower

18. The system as recited in claim 17 wherein each of the plurality of vertical blades in a direction opposite the curve of the plurality of fins.
